(19) United States
(12) Patent Application Publication
(10) Pub. No.: US 2026/0214996 A1
(43) Pub. Date: Jul. 23, 2026

(54) SEMICONDUCTOR DEVICE AND MANUFACTURING METHOD THEREOF

(71) Applicant: DYNAX SEMICONDUCTOR, INC., Kunshan (CN)

(72) Inventors: Naiqian ZHANG, Kunshan (CN); Linlin SUN, Kunshan (CN)

(21) Appl. No.: 19/144,695

(22) PCT Filed: Dec. 20, 2023
(86) PCT No.: PCT/CN2023/140256

§ 371 Date: Jun. 30, 2025

(30) Foreign Application Priority Data
Dec. 30, 2022 (CN) 202211739701.8

(51) Int. Cl. H10D 89/10; H10D 30/01; H10D 30/47; H10D 62/10; H10D 62/824; H10W 20/41; H10W 20/42; H10W 20/43

(52) U.S. Cl. CPC H10D 89/105; H10D 30/015; H10D 30/475; H10D 62/126; H10D 62/824; H10W 20/422; H10W 20/43; H10W 20/435

(57) ABSTRACT

Embodiments of the present disclosure provide a semiconductor device and a manufacturing method thereof, the semiconductor device including a substrate, an epitaxial structure located at a side of the substrate, a plurality of gates located at a side of the epitaxial structure away from the substrate, the gates extending along a first direction, and the plurality of the gates being arranged along a second direction, the first direction and the second direction intersecting with each other and each being parallel to a plane where the substrate is located, the plurality of the gates include a first gate and a second gate, and along the second direction, the first gate being located at a side of the second gate near an edge of the semiconductor device, and the highest temperature of the first gate is T1, and the highest temperature of the second gate is T2, wherein (T2−T1)/T1≤20%.

### CROSS REFERENCE TO RELATED APPLICATIONS

This patent application is a National Stage Entry of PCT/CN2023/140256 filed on Dec. 20, 2023, which claims the benefit and priority of Chinese Patent Application No. 202211739701.8 filed on Dec. 30, 2022, the disclosures of which are incorporated by reference herein in their entirety as part of the present application.

### BACKGROUND

Embodiments of the present disclosure relate to the field of semiconductor technology, and in particular to a semiconductor device and a manufacturing method thereof.

A GaN (Gallium Nitride) semiconductor device has significant advantages such as wide forbidden band, high electron mobility, high breakdown field strength, and high-temperature resistance, compared with first-generation silicon semiconductor and second-generation gallium arsenide semiconductor, it is more suitable for fabricating a high-temperature, high-voltage, high-frequency and high-power electronic device, has broad application prospects, can be widely used in the fields of radio frequency microwave and power electronics, and has become a hot spot of research in the current semiconductor industry.

Currently, 5G communication imposes increasingly higher requirements on the bandwidth and operating frequency of a semiconductor chip, a Gallium Nitride High Electron Mobility Transistor is a high electron mobility device formed by utilizing the two-dimensional electron gas at the AlGaN/GaN heterojunction, it can be better applied in fields of high frequency, high voltage and high power, and is naturally favored in the field of 5G communication.

For a GaN RF power amplifier, improving the power and RF performance of the device is what the GaN RF chip has been pursuing. However, during the design and use of a semiconductor device, there are many factors that will affect the output power, RF performance and reliability of the device, for example, uneven temperature distribution within the device can lead to high heat generation and low reliability of the device, which in turn can impact the output power and reliability of the device. Therefore, in the design process of a semiconductor device, how to achieve an even temperature distribution within the semiconductor device is a highly critical technology.

### BRIEF DESCRIPTION

In view of this, embodiments of the present disclosure provide a semiconductor device and a manufacturing method thereof to achieve an even temperature distribution of the semiconductor device, which can reduce the degradation of the device's RF performance and improve the output power.

In a first aspect, embodiments of the present disclosure provide a semiconductor device including:
a substrate;
an epitaxial structure located at a side of the substrate; and
a plurality of gates located at a side of the epitaxial structure away from the substrate, the gates extending along a first direction, and the plurality of the gates being arranged along a second direction; the first direction and the second direction intersecting with each other and each being parallel to a plane where the substrate is located;
the plurality of the gates include a first gate and a second gate, and along the second direction, the first gate being located at a side of the second gate near an edge of the semiconductor device; the highest temperature of the first gate is T1, and the highest temperature of the second gate is T2, wherein (T2−T1)/T1≤20%.

The semiconductor device may further include a plurality of sources located at a side of the epitaxial structure away from the substrate, the sources extending along the first direction, and the plurality of the sources being arranged along the second direction;
the plurality of the sources include a first source and a second source, and along the second direction, the first source being disposed adjacent to the first gate and the second source being disposed adjacent to the second gate, and the first source being located at a side of the second source near an edge of the semiconductor device; and
the semiconductor device further includes vias penetrating through the substrate and the epitaxial structure, the vias including a first type of vias and a second type of vias, and along a thickness direction of the semiconductor device, the first source being overlapped with the first type of vias, and the second source being overlapped with the second type of vias;
wherein a sum of opening area of the first type of vias is greater than a sum of opening area of the second type of vias.

The first type of vias may include at least one first via and the second type of vias may include at least one second via; and
an opening area of the first via is larger than an opening area of the second via.

Along the second direction, the first via may be located at a side of any other via near an edge of the semiconductor device, and the second via may be located at a side of any other via near a center of the semiconductor device; and
an opening area of the vias gradually decreases along a direction of the first via pointing to the second via.

Along the second direction, the first via may be located at a side of any other via near an edge of the semiconductor device, and the second via may be located at a side of any other via near the center of the semiconductor device; and
the opening area of the first via is S1 and the opening area of the second via is S2, wherein S2<S1≤4*S2.

The first type of vias may include at least two first vias and the second type of vias may include at least one second via; and
the number of the first vias is greater than the number of the second vias.

Along the second direction, the first via may be located at a side of any other via near an edge of the semiconductor device, and the second via may be located at a side of any other via near the center of the semiconductor device; and
the number of the vias gradually decreases along a direction of the first via pointing to the second via.

Along the second direction, the first via may be located at a side of any other via near an edge of the semiconductor device, and the second via may be located at a side of any other via near the center of the semiconductor device; and
the number of the first vias in the first type of vias is n1 and the number of the second vias in the second type of vias is n2, wherein (n1−n2)≤5.

The semiconductor device may further include a plurality of sources located at a side of the epitaxial structure away from the substrate, the sources extending along the first direction, and the plurality of the sources being arranged along the second direction;
the plurality of the sources include a first source and a second source, and along the second direction, the first source being disposed adjacent to the first gate and the second source being disposed adjacent to the second gate, and the first source being located at a side of the second source near an edge of the semiconductor device;
the semiconductor device further includes vias penetrating through the substrate and the epitaxial structure, the vias including a first type of vias and a second type of vias, and along a thickness direction of the semiconductor device, the first source being overlapped with the first type of vias, and the second source being overlapped with the second type of vias; and
along the first direction, a center of the first type of vias is located at a side, which is near to a center of the semiconductor device, of a center of the second type of vias.

Along the second direction, there may be a gate spacing between two of the gates that is adjacent to each other;
the plurality of the gate spacings may include a first gate spacing along a side of the second direction near an edge of the semiconductor device and a second gate spacing located at a side of the first gate spacing away from the edge of the semiconductor device; and
along the second direction, the first gate spacing being less than the second gate spacing.

The second gate spacing may be located at a side of any other gate spacing near a center of the semiconductor device; and
the gate spacing gradually increases along a side of the first gate spacing pointing to the second gate spacing.

In a second aspect, embodiments of the present disclosure further provide a method of manufacturing a semiconductor device, including:
providing a substrate;
fabricating an epitaxial structure at a side of the substrate; and
fabricating a plurality of gates at a side of the epitaxial structure away from the substrate, the gates extending along a first direction, and the plurality of the gates being arranged along a second direction; the first direction and the second direction intersecting with each other and each being parallel to a plane where the substrate is located; the plurality of the gates include a first gate and a second gate, and along the second direction, the first gate being located at a side of the second gate near an edge of the semiconductor device; the highest temperature of the first gate is T1, and the highest temperature of the second gate is T2, wherein (T2−T1)/T1≤20%.

The semiconductor device provided in embodiments of the present disclosure, by disposing the plurality of gates at a side of the epitaxial structure away from the substrate, and a first gate among the plurality of gates being located at a side of the second gate near the edge of the semiconductor device, and by making the highest temperature T1 of the first gate and the highest temperature T2 of the second gate satisfy (T2−T1)/T1≤20%, can ensure a smaller temperature difference among the gates, which in turn enable an even temperature distribution of the semiconductor device, and can reduce the degradation of the device's RF performance and improve the output power.

### BRIEF DESCRIPTION OF THE DRAWINGS

FIG. 1 is a structural diagram of a semiconductor device provided in an embodiment of the present disclosure;

FIG. 2 is a cross-sectional structural diagram of the semiconductor device provided in FIG. 1 along a section line A-A′;

FIG. 3 is a cross-sectional structural diagram of the semiconductor device provided in FIG. 1 along a section line B-B′;

FIG. 4 is a structural diagram of another semiconductor device provided in an embodiment of the present disclosure;

FIG. 5 is a structural diagram of yet another semiconductor device provided in an embodiment of the present disclosure;

FIG. 6 is a structural diagram of yet another semiconductor device provided in an embodiment of the present disclosure;

FIG. 7 is a structural diagram of yet another semiconductor device provided in an embodiment of the present disclosure; and

FIG. 8 is a flowchart of a method of manufacturing a semiconductor device provided in an embodiment of the present disclosure.

### DETAILED DESCRIPTION

The present disclosure is described in further detail below in connection with the accompanying drawings and embodiments. It is to be understood that the specific embodiments described herein are for the purpose of explaining the present disclosure only and are not a limitation of the disclosure. It is also to be noted that, for ease of description, only portions related to the present disclosure are shown in the accompanying drawings, rather than the entire structure.

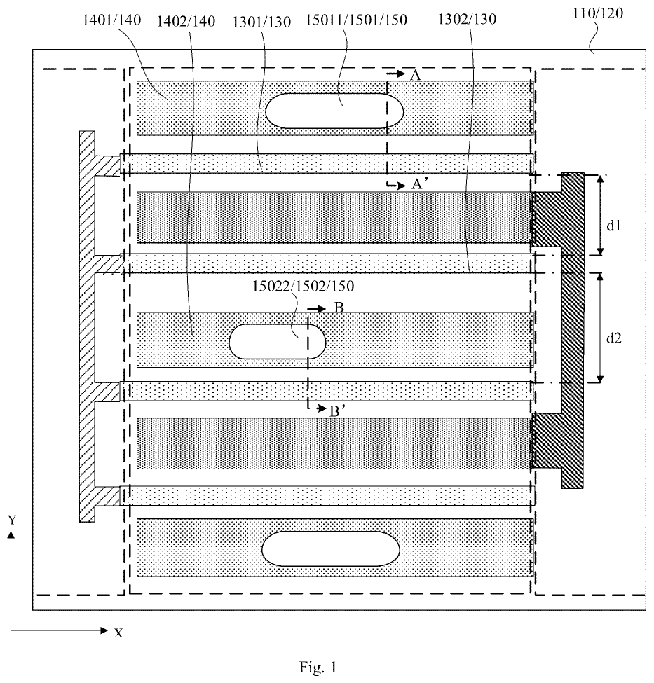

FIG. 1 is a structural diagram of a semiconductor device provided in an embodiment of the present disclosure. As shown in FIG. 1, the semiconductor device includes a substrate 110, an epitaxial structure 120 located at a side of the substrate 110, a plurality of gates 130 located at a side of the epitaxial structure 120 away from the substrate 110, the gates 130 extending along a first direction (the X direction as shown in FIG. 1), and the plurality of gates 130 being arranged along a second direction (the Y direction as shown in FIG. 1); the first direction X and the second direction Y intersecting with each other and each being parallel to a plane where the substrate 110 is located; the plurality of gates 130 include a first gate 1301 and a second gate 1302, and along the second direction Y, the first gate 1301 being located at a side of the second gate 1302 near an edge of the semiconductor device; the highest temperature of the first gate 1301 is T1, and the highest temperature of the second gate 1302 is T2, wherein (T2−T1)/T1≤20%.

Specifically, with continued reference to FIG. 1, the material of the substrate 110 may be formed from one or more of silicon, sapphire, silicon carbide, gallium arsenide, gallium nitride, diamond, or other materials suitable for growing gallium nitride. The epitaxial structure 120 is located at a side of the substrate 110, and specifically, the epitaxial structure 120 may be a semiconductor material of group III-V compounds, and may be formed from one or more of gallium arsenide, aluminum gallium arsenide, gallium nitride, aluminum gallium nitride, or indium gallium nitride, for example.

Further, as to the plurality of gates 130 located at a side of the epitaxial structure 120 away from the substrate 110, the first gate 1301 of the plurality of gates 130 is located at a side of the second gate 1302 near the edge of the semiconductor device, and since during the operation of the semiconductor device, each gate 130 located at an active region will generate a self-heating effect, i.e., a thermal effect generated by each gate itself. And since the self-heating generated by each gate 130 will spread to the neighboring gates 130, i.e., a mutual heating effect will also be generated between two neighboring gates 130. In other words, during normal operation of the semiconductor device, each gate 130 generates both a self-heating effect and a mutual heating effect, and the temperature of each gate 130 is obtained by superimposing the temperature generated by the self-heating effect and the temperature generated by the mutual heating effect. It can be appreciated that, the difference in the temperature generated by each gate 130 due to the self-heating effect is small, but since along the second direction Y, the first gate 1301 is located at a side near the edge of the semiconductor device, the number of gates 130 adjacent to the first gate 1301 is small, which results in the temperature generated by the first gate 1301 due to the mutual heating effect being low.

Specifically, by making the highest temperature T1 of the first gate 1301 and the highest temperature T2 of the second gate satisfy (T2−T1)/T1≤20%, the temperature difference between the highest temperature T1 of the first gate 1301, which is located at a side near the edge of the semiconductor device, and the highest temperature T2 of the second gate 1302 can be made relatively small, which in turn enable an even temperature distribution of the semiconductor device, thereby reducing the thermal loss of the device, and improving the output power of the semiconductor device.

The semiconductor device provided in embodiments of the present disclosure, by disposing the plurality of gates at a side of the epitaxial structure away from the substrate, and a first gate among the plurality of gates being located at a side of the second gate near the edge of the semiconductor device, and by making the highest temperature T1 of the first gate and the highest temperature T2 of the second gate satisfy (T2−T1)/T1≤20%, can ensure a smaller temperature difference among the gates, which in turn enable an even temperature distribution of the semiconductor device, and can reduce the degradation of RF performance and improve the output power.

With continued reference to FIG. 1, the highest temperature of any two adjacent gates 130 may be similar.

Specifically, the highest temperature of any two adjacent gates 130 being similar can ensure an even temperature distribution of the semiconductor device, thereby sufficiently reducing the degradation of RF performance.

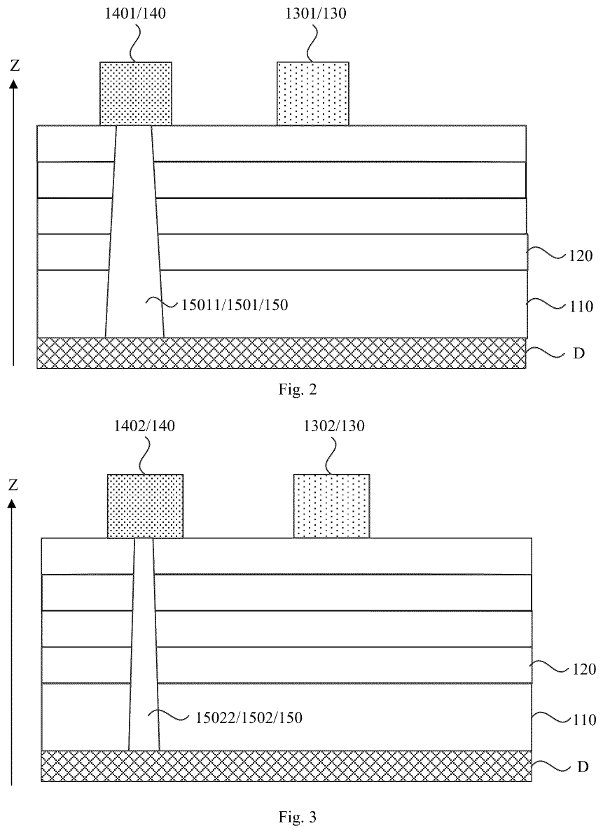

FIG. 2 is a cross-sectional structural diagram of the semiconductor device provided in FIG. 1 along a section line A-A′. Referring to FIG. 1 and FIG. 2, the semiconductor device further includes a plurality of sources 140 located at a side of the epitaxial structure 120 away from the substrate 110, the sources 140 extending along a first direction X, and the plurality of sources 140 being arranged along a second direction Y; the plurality of sources 140 includes a first source 1401 and a second source 1402, and along the second direction Y, the first source 1401 being disposed adjacent to the first gate 1301 and the second source 1402 being disposed adjacent to the second gate 1302, and the first source 1401 is located at a side of the second source 1402 near the edge of the semiconductor device; the semiconductor device also includes vias 150 penetrating through the substrate 110 and the epitaxial structure 120, the vias 150 include a first type of vias 1501 and a second type of vias 1502, and along a thickness direction of the semiconductor device (the Z direction as shown in FIG. 2), the first source 1401 being overlapped with the first type of vias 1501, and the second source 1402 being overlapped with the second type of vias 1502; wherein a sum of opening area of the first type of vias 1501 is greater than a sum of opening area of the second type of vias 1502.

Specifically, the source 140 may be connected to the backside of the semiconductor device through the vias 150, and exemplarily, the vias 150 can penetrate through the substrate 110 and the epitaxial structure 120, that is, being connected to the source 140 via the source signal input electrode D located at a side of the substrate 110 away from the epitaxial structure 120, that is to say, the source 140 is electrically connected to the source signal input electrode D through the vias 150. Exemplarily, it is also possible to perform puncturing when the substrate 110 and the epitaxial structure 120 are fabricated sequentially, and fill the holes in the substrate 110 and each layer of the epitaxial structure 120 with a metallic connecting material, which in turn can electrically connect the source signal input electrode D to the source 140.

It should be noted that, since the vias 150 penetrate through the substrate 110 and the epitaxial structure 120, i.e., the vias 150 have poorer thermal conductivity compared to the substrate 110, the temperature at the vias 150 is higher. In addition, the larger the area of the vias 150, the poorer the thermal conductivity and the higher the temperature.

Further, the vias 150 include a first type of vias 1501 and a second type of vias 1502, and a sum of opening area of the first type of vias 1501 is greater than a sum of opening area of the second type of vias 1502, that is, a product of the number of the first type of vias 1501 and an area of a single via 1501 of the first type is greater than a product of the number of the second type of vias 1502 and an area of a single via 1502 of the second type, so that the temperature between the first gate 1301 and the second gate 1302 can be balanced, i.e., the temperature at the first type of vias 1501 is higher compared to the temperature at the second type of vias 1502, which can neutralize the smaller mutual heating effect at the first gate 1301, which in turn can ensure a smaller temperature difference between the first gate 1301 and the second gate 1302, thereby achieving an even temperature distribution of the semiconductor device.

FIG. 3 is a cross-sectional structural diagram of the semiconductor device provided in FIG. 1 along a section line B-B′. Referring to FIGS. 1-3, the first type of vias 1501 include at least one first via 15011, and the second type of vias 1502 include at least one second via 15022; an opening area of the first via 15011 is larger than an opening area of the second via 15022.

Specifically, an opening area of the first via 15011 is larger than an opening area of the second via 15022, i.e., compared to the second via 15022, the first via 15011 has a larger opening area, so that the first type of vias 1501 including at least one first via 15011 will have a larger sum of opening area, which can ensure that the first type of vias 1501 dissipate less heat and have a higher temperature, which in turn can neutralize the smaller mutual heating effect of the first gate 1301, realize an even temperature distribution of the semiconductor device, and be able to reduce the RF performance degradation of the device and increase the output power.

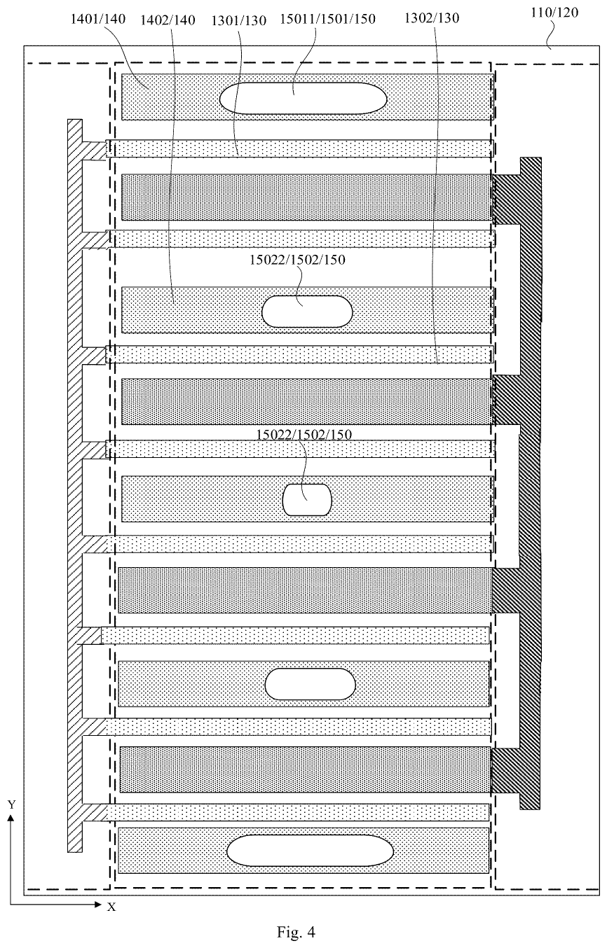

FIG. 4 is a structural diagram of another semiconductor device provided in an embodiment of the present disclosure. As shown in FIG. 4, along the second direction Y, the first via 15011 is located at a side of any other via 150 near an edge of the semiconductor device, and the second via 15022 is located at a side of any other via 150 near the center of the semiconductor device, and the opening area of the vias 150 gradually decreases along a direction of the first via 15011 pointing to the second via 15022.

Exemplarily, that the first via 15011 may be located at a side near an edge of the semiconductor device may be understood as the first via is located at a position near the edge of the semiconductor device and on both sides of the semiconductor device along the second direction Y. That the second via 15022 is located at a side of any other via 150 near the center of the semiconductor device may be understood as the second via 15022 covers the center of the semiconductor device or a distance between the second via 15022 and the center of the semiconductor device is less than a distance between any other via 150 and the center of the semiconductor device.

Specifically, along a direction of the first via 15011 pointing to the second via 15022, an opening area of the vias 150 gradually decreases, that is, along the second direction Y, i.e., a direction from both sides of the second direction Y toward the center of the semiconductor device, an opening area of the vias 150 gradually decreases, that is, the opening area of the first via 15011 is larger than the opening area of the second via 15022, which can ensure that the first via 15011 dissipates less heat, this in turn can neutralize the smaller mutual heating effect of the first gate 1301, which in turn can ensure that the temperature difference between the first gate 1301 and the second gate 1302 is smaller, thereby realizing an even temperature distribution of the semiconductor device, and being able to reduce the RF performance degradation of the device and increase the output power.

With continued reference to FIG. 1, along the second direction Y, the first via 15011 may be located at a side of any other via 150 near an edge of the semiconductor device, and the second via 15022 is located at a side of any other via 150 near the center of the semiconductor device; the opening area of the first via 15011 is S1, and the opening area of the second via 15022 is S2, wherein S2<S1≤4*S2.

Specifically, an opening area S1 of the first via 15011 and an opening area S2 of the second via 15022 satisfy S2<S1≤4*S2, so that on one hand, it can realize that the heat dissipation of the first via 15011 is less, and on the other hand, it can avoid that the opening area of the first via 15011 is so large as to impact the normal heat dissipation of the semiconductor device, while ensuring that fabrication of the vias can meet the process requirements.

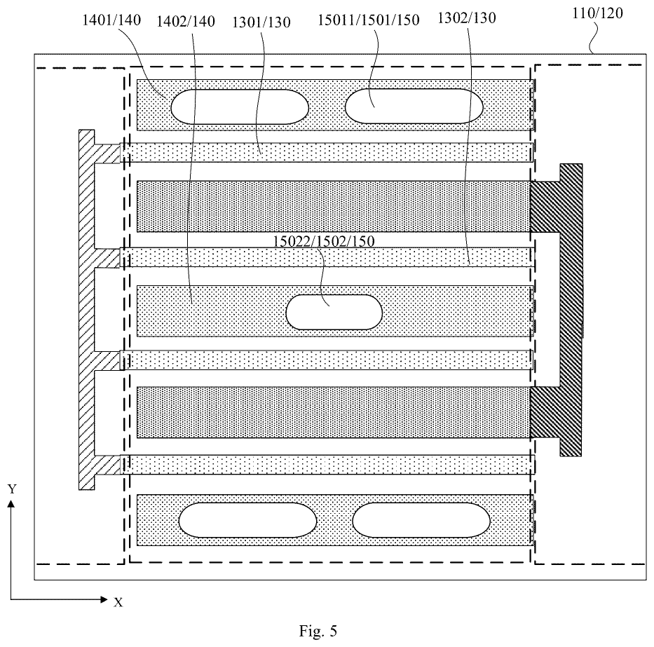

FIG. 5 is a structural diagram of yet another semiconductor device provided in an embodiment of the present disclosure. As shown in FIG. 5, the first type of vias 1501 include at least two first vias 15011, and the second type of vias 1502 include at least one second via 15022; the number of first vias 15011 is larger than the number of second vias 15022.

Specifically, the number of the first vias 15011 is greater than the number of the second vias 15022, and by setting the number of the first vias 15011 to be greater, the temperature difference between the first gate 1301 and the second gate 1302 can be balanced, which in turn can ensure that there is a higher temperature at the first via 15011 to neutralize the smaller mutual heating effect of the first gate 1301, thereby achieving an even temperature distribution of the semiconductor device, which can reduce the degradation of the device's RF performance and improve the output power.

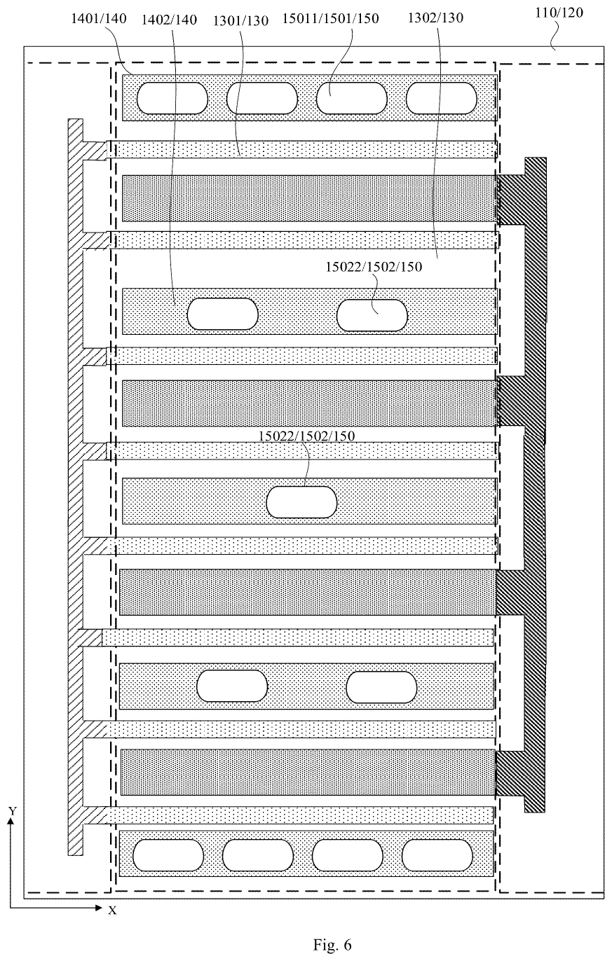

FIG. 6 is a structural diagram of yet another semiconductor device provided in an embodiment of the present disclosure. As shown in FIG. 6, along the second direction Y, the first via 15011 is located at a side of any other via 150 near the edge of the semiconductor device, and the second via 15022 is located at a side of any other via 150 near the center of the semiconductor device; and along a direction of the first via 15011 pointing to the second via 15022, the number of vias 150 gradually decreases.

Specifically, along the direction of the first via 15011 pointing to the second via 15022, the number of vias 150 gradually decreases, so that by setting the number of the first vias 15011 to be greater, on one hand, it can ensure that the temperature at the first via 15011 is higher and can neutralize the smaller mutual heating effect of the first gate 1301, thus making the temperature of the semiconductor device evenly distributed, reducing thermal loss of the device, and on the other hand, it can simplify the via fabricating process.

With continued reference to FIG. 5, along the second direction Y, the first via 15011 is located at a side of any other via 150 near the edge of the semiconductor device, and the second via 15022 is located at a side of any other via 150 near the center of the semiconductor device; the number of the first vias 15011 in the first type of vias 1501 is n1, and the number of the second vias 15022 in the second type of vias 1502 is n2, where n1−n2≤5.

Specifically, the number n1 of the first vias 15011 and the number n2 of the second vias 15022 satisfy (n1−n2)≤5, so that on one hand, it can ensure that the number of the first vias 15011 is larger relative to the second vias 15022, i.e., it can balance the temperature difference between the first gate 1301 and the second gate 1302, and on the other hand, it can ensure the overall heat dissipation of the semiconductor device, preventing excessive vias from compromising the overall heat dissipation of the semiconductor device, and maintaining normal operation of the semiconductor device; furthermore, it can simplify the via fabrication process and prevent an excessive number of vias from increasing the fabrication complexity of the semiconductor device.

With continued reference to FIG. 1, the semiconductor device further includes a plurality of sources 140 located at a side of the epitaxial structure 120 away from the substrate 110, the sources 140 extending along a first direction X, and the plurality of sources 140 being arranged along a second direction Y; the plurality of sources 140 include a first source 1401 and a second source 1402, and along the second direction Y, the first source 1401 being disposed adjacent to the first gate 1301 and the second source 1402 being disposed adjacent to the second gate 1302, and the first source 1401 being located at a side of the second source 1402 near an edge of the semiconductor device; the semiconductor device further includes vias 150 penetrating through the substrate 110 and the epitaxial structure 120, the vias 150 including a first type of vias 1501 and a second type of vias 1502, and along a thickness direction Z of the semiconductor device, the first source 1401 being overlapped with the first type of vias 1501, and the second source 1402 being overlapped with the second type of vias 1502; along the first direction X, a center of the first type of vias 1501 is located at a side, which is near to a center of the semiconductor device, of a center of the second type of vias 1502.

It should be noted that, when the semiconductor device is operating, along the first direction X, the center of the semiconductor device generates more heat, and thus the temperature is higher. Specifically, along the first direction X, the center of the first type of vias 1501 is located at a side, which is near to the center of the semiconductor device, of the center of the second type of vias 1502, so that it can ensure that the temperature at the first via 15011 is higher, which in turn can neutralize the smaller mutual heating effect of the first gate 1301, balance the temperature difference between the first gate 1301 and the second gate 1302, and reduce the degradation of RF performance.

With continued reference to FIG. 1, along the second direction Y, there is a gate spacing between two of the gates 130 that adjacent to each other; a plurality of the gate spacings include a first gate spacing d1 along a side of the second direction Y near an edge of the semiconductor device and a second gate spacing d2 located at a side of the first gate spacing d1 away from the edge of the semiconductor device; and along the second direction Y, the first gate spacing d1 being smaller than the second gate spacing d2.

It is to be noted that, the larger the gate spacing between two adjacent gates 130, the smaller the influence of the mutual heating. Specifically, along the second direction Y, the first gate spacing d1 is smaller than the second gate spacing d2, that is, the first gate spacing d1 near the edge of the semiconductor device is smaller, and the influence of the mutual heating is larger, and in order to balance the difference in mutual heating between the first gate 1301 and the second gate 1302, it is set that the first gate spacing d1 is smaller than the second gate spacing d2 along the second direction Y, so as to be able to reduce the temperature difference between the first gate 1301 and the second gate 1302, thus enable an even temperature distribution of the semiconductor device, which can reduce the RF performance degradation of the device and increase the output power.

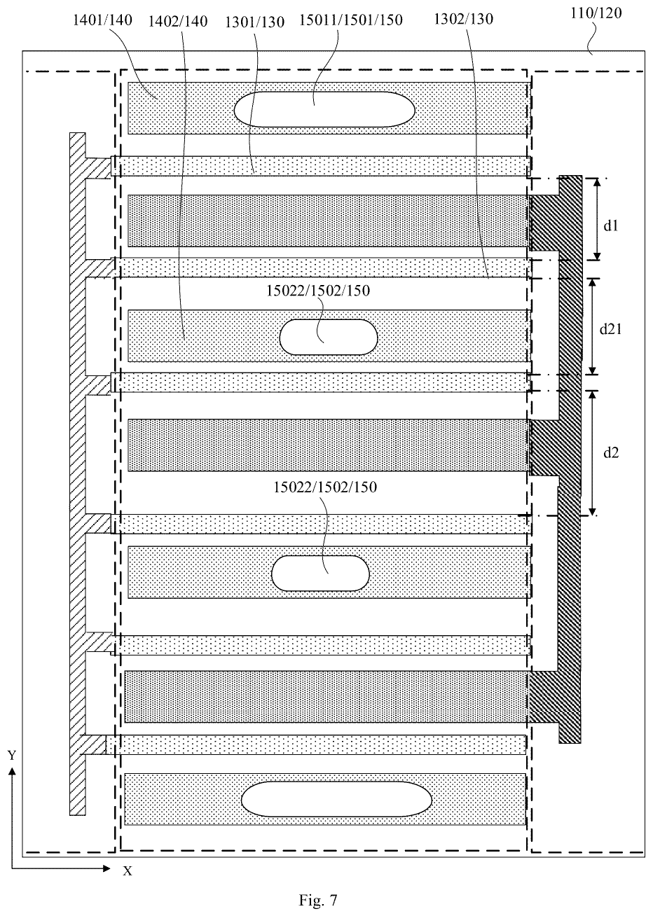

FIG. 7 is a structural diagram of yet another semiconductor device provided in an embodiment of the present disclosure. As shown in FIG. 7, a second gate spacing d2 is located at a side of any other gate spacing near a center of the semiconductor device; the gate spacing gradually increases along a side of the first gate spacing d1 pointing to the second gate spacing d2.

Specifically, with continued reference to FIG. 7, the gate spacing between the first gate 1301 and the adjacent second gate 1302 is d1, and the gate spacings between the two adjacent second gates 1302 are d21 and d2, respectively, and d1<d21<d2, i.e., the gate spacing gradually increases along a side of the first gate spacing d1 pointing to the second gate spacing d2, and this can be understood as the maximum gate spacing is located at a center position of the semiconductor device, which facilitates reducing the mutual heating effect of the second gate 1302; and this can also be understood as the gate spacing gradually decreases from the center position of the semiconductor device to a direction away from the center position, thus being able to balance the difference in mutual heating between the first gate 1301 and the second gate 1302, that is, to be able to reduce the temperature at the center of the semiconductor device, which in turn achieving an even temperature distribution of the semiconductor device, that it, is possible to reduce the thermal loss of the device.

It should be appreciated that embodiments of the present disclosure improve the output power of a semiconductor device from the perspective of its structural design. The semiconductor device includes, but is not limited to: high-power gallium nitride High Electron Mobility Transistor (HEMT for short) operating in a high-voltage and high-current environment, transistor with a Silicon-On-Insulator (SOI for short) structure, gallium arsenide (GaAs)-based transistor as well as Metal-Oxide-Semiconductor Field-Effect Transistor (MOSFET for short), Metal-Semiconductor Field-Effect Transistor (MISFET for short), Double Heterojunction Field-Effect Transistor (DHFET for short), Junction Field-Effect Transistor (JFET for short), Metal-Semiconductor Field-Effect Transistor (MESFET for short), Metal-Semiconductor Heterojunction Field-Effect Transistor (MISHFET for short), or other field-effect transistors.

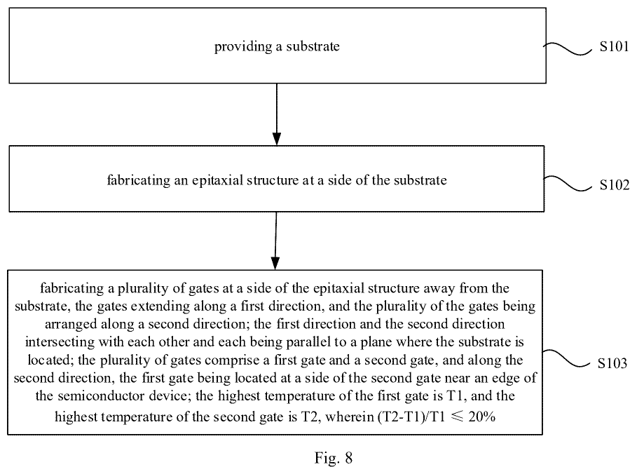

Based on the same inventive concept, embodiments of the present disclosure also provide a method of manufacturing a semiconductor device, as shown in FIG. 8, the method of manufacturing a semiconductor device provided by embodiments of the present disclosure may include:

S101, providing a substrate.

Exemplarily, the material of the substrate may be Si, SiC, or sapphire, and may also be other materials suitable for growing gallium nitride. The substrate may be manufactured by an atmospheric pressure chemical vapor deposition method, a sub-normal pressure chemical vapor deposition method, a metal organic compound vapor deposition method, a low pressure chemical vapor deposition method, a high-density plasma chemical vapor deposition method, an ultra-high vacuum chemical vapor deposition method, a plasma-enhanced chemical vapor deposition method, a catalytic chemical vapor deposition method, a mixed physical chemical vapor deposition method, a fast thermal chemical vapor deposition method, a vapor phase epitaxy method, a pulsed laser deposition method, an atomic layer epitaxy method, a molecular beam epitaxy method, a sputtering method or an evaporation method.

S102, fabricating an epitaxial structure at a side of the substrate.

Exemplarily, the epitaxial structure may be formed from one or more of Group III-V nitrides such as gallium nitride (GaN), aluminum gallium nitride (AlGaN), indium gallium nitride (InGaN), aluminum nitride (AlN), or indium aluminum gallium nitride (InAlGaN), and a two-dimensional electron gas (2 DEG) may be formed within the epitaxial structure. The method for growing the epitaxial structure includes metal-organic chemical vapor deposition (MOCVD), hydride vapor phase epitaxy (HVPE), molecular beam epitaxy (MBE), and liquid-phase epitaxy (LPE), and the like, embodiments of the present disclosure have no limitation thereto. Specifically, a two-dimensional electron gas is formed in the epitaxial structure.

The epitaxial structure may include a nucleation layer, a buffer layer, a channel layer, and a barrier layer.

Exemplarily, the material of the nucleation layer may be aluminum nitride, which is located between the substrate and the buffer layer, and serves to bond the semiconductor material layer to be grown next. The buffer layer is located at a side of the substrate, the material of the buffer layer may be gallium nitride, and the buffer layer may include iron atoms therein, which facilitates realizing high resistivity in the buffer layer, ensuring that vertical leakage can be blocked as well as improving pinch-off performance of the semiconductor device.

Exemplarily, the channel layer can be a Group III nitride, such as AlxGal-xN, wherein 0≤x<1, i.e., it may be at an interface between the channel layer and the barrier layer, i.e., the energy at the conduction band edge of the channel layer is less than the energy at the conduction band edge of the barrier layer. Exemplarily, x=0 indicates that the channel layer is GaN. The channel layer may also be other Group III nitride, for example it may be InGaN, AlInGaN. The channel layer may be undoped or unintentionally doped. The channel layer may also be a multilayer structure, for example, it may be a combination of a superlattice, GaN, or AlGaN.

Exemplarily, the barrier layer is fabricated at a side of the channel layer away from the substrate, and the barrier layer forms a heterojunction structure with the channel layer. The barrier layer may be AIN, AlInN, AlGaN, or AlInGaN. The barrier layer has a sufficient thickness and has a sufficiently high Al component such that doping forms a significant carrier concentration at the interface between the channel layer and the barrier layer. Exemplarily, the thickness of the barrier layer may be 20 nm and the doping concentration of the Al component may be 25%.

Exemplarily, the channel layer may include GaN and the barrier layer may include AlGaN, i.e., the material of the barrier layer has a higher bandgap than the material of the channel layer, and the channel layer may also have a greater electron affinity than the barrier layer. Due to the bandgap difference between the barrier layer and the channel layer and the piezoelectric effect at the interface between the barrier layer and the channel layer, a two-dimensional electron gas is formed in the channel layer and the barrier layer.

It is appreciated that the epitaxial structure may further include a cap layer, the cap layer being located at a surface of the barrier layer away from the substrate. The cap layer can reduce the surface state, reduce the surface leakage of the subsequent semiconductor device, and inhibit the current collapse, thereby enhancing the performance and reliability of the epitaxial structure as well as the semiconductor device.

S103: fabricating a plurality of gates at a side of the epitaxial structure away from the substrate, the gates extending along a first direction, and the plurality of the gates being arranged along a second direction; the first direction and the second direction intersecting with each other and each being parallel to a plane where the substrate is located; the plurality of gates include a first gate and a second gate, and along the second direction, the first gate being located at a side of the second gate near an edge of the semiconductor device; the highest temperature of the first gate is T1, and the highest temperature of the second gate is T2, wherein (T2−T1)/T1≤20%.

Specifically, with reference to FIG. 1, the plurality of gates 130 are fabricated at a side of the epitaxial structure 120 away from the substrate 110, the first gate 1301 of the plurality of gates 130 is located at a side of the second gate 1302 near the edge of the semiconductor device, and since during the operation of the semiconductor device, each gate 130 located at an active region will generate a self-heating effect, i.e., a thermal effect generated by each gate itself. And since the self-heating generated by each gate 130 will spread to the neighboring gates 130, i.e., a mutual heating effect will also be generated between two neighboring gates 130. In other words, during normal operation of the semiconductor device, each gate 130 generates both a self-heating effect and a mutual heating effect, and the temperature of each gate 130 is obtained by superimposing the temperature generated by the self-heating effect and the temperature generated by the mutual heating effect. It can be appreciated that, the difference in the temperature generated by each gate 130 due to the self-heating effect is small, but since along the second direction Y, the first gate 1301 is located at a side near the edge of the semiconductor device, the number of gates 130 adjacent to the first gate 1301 is small, which results in the temperature generated by the first gate 1301 due to the mutual heating effect being low.

Specifically, with continued reference to FIG. 1, by making the highest temperature T1 of the first gate 1301 and the highest temperature T2 of the second gate satisfy (T2−T1)/T1≤20%, the temperature difference between the highest temperature T1 of the first gate 1301, which is located at a side near the edge of the semiconductor device, and the highest temperature T2 of the second gate 1302 can be made relatively small, which in turn enable an even temperature distribution of the semiconductor device, thereby reducing the thermal loss of the device, and improving the output power of the semiconductor device.

The method of manufacturing a semiconductor device provided in embodiments of the present disclosure, by fabricating the plurality of gates at a side of the epitaxial structure away from the substrate, and a first gate among the plurality of gates being located at a side of the second gate near the edge of the semiconductor device, and by making the highest temperature T1 of the first gate and the highest temperature T2 of the second gate satisfy (T2−T1)/T1≤20%, can ensure a smaller temperature difference among the gates, which in turn enable an even temperature distribution of the semiconductor device, and can reduce the degradation of RF performance and improve the output power.

Note that the foregoing are merely example embodiments of the present disclosure and the technical principles utilized. It is appreciated by those skilled in the art that the present disclosure is not limited to the particular embodiments described herein, and various obvious changes, rearrangements, combinations and substitutions can be made by those skilled in the art without departing from the protection scope of the disclosure. Therefore, while the present disclosure has been described in greater detail through the foregoing embodiments, the present disclosure is not limited to the above embodiments, it may include further equivalent embodiments without departing from the idea of the present disclosure, and the scope of the present disclosure is defined by the scope of the appended claims.

1. A semiconductor device comprising:
a substrate;
an epitaxial structure located at a side of the substrate; and
a plurality of gates located at a side of the epitaxial structure opposite the substrate, the gates extending along a first direction, and the plurality of the gates being arranged along a second direction, wherein the first direction and the second direction intersecting with each other and each being parallel to a plane where the substrate is located;
wherein the plurality of the gates comprise a first gate and a second gate, and along the second direction, the first gate is located at a side of the second gate near an edge of the semiconductor device, wherein the highest temperature of the first gate is T1, the highest temperature of the second gate is T2, and wherein (T2−T1)/T1≤20%.

2. The semiconductor device according to claim 1, wherein the semiconductor device further comprises a plurality of sources located at a side of the epitaxial structure opposite the substrate, the sources extending along the first direction, and the plurality of the sources arranged along the second direction;
wherein the plurality of the sources comprise a first source and a second source, and along the second direction, the first source is disposed adjacent to the first gate and the second source is disposed adjacent to the second gate, and the first source is located at a side of the second source near an edge of the semiconductor device;
wherein the semiconductor device further comprises vias penetrating through the substrate and the epitaxial structure, the vias comprising a first type of vias and a second type of vias, and along a thickness direction of the semiconductor device, the first source is overlapped with the first type of vias, and the second source is overlapped with the second type of vias; and
wherein a sum of opening area of the first type of vias is greater than a sum of opening area of the second type of vias.

3. The semiconductor device according to claim 2, wherein the first type of vias comprise at least one first via and the second type of vias comprise at least one second via; and
wherein an opening area of the first via is larger than an opening area of the second via.

4. The semiconductor device according to claim 3, wherein, along the second direction, the first via is located at a side of any other via near an edge of the semiconductor device, and the second via is located at a side of any other via near a center of the semiconductor device; and
wherein an opening area of the vias gradually decreases along a direction of the first via pointing to the second via.

5. The semiconductor device according to claim 3, wherein, along the second direction, the first via is located at a side of any other via near an edge of the semiconductor device, and the second via is located at a side of any other via near a center of the semiconductor device; and
wherein the opening area of the first via is S1, wherein the opening area of the second via is S2, and wherein S2<S1≤4*S2.

6. The semiconductor device according to claim 2, wherein the first type of vias comprise at least two first vias and the second type of vias comprise at least one second via; and
wherein the number of the first vias is greater than the number of the second vias.

7. The semiconductor device according to claim 6, wherein, along the second direction, the first via is located at a side of any other via near an edge of the semiconductor device, and the second via is located at a side of any other via near a center of the semiconductor device; and
wherein the number of the vias gradually decreases along a direction of the first via pointing to the second via.

8. The semiconductor device according to claim 6, wherein, along the second direction, the first via is located at a side of any other via near an edge of the semiconductor device, and the second via is located at a side of any other via near a center of the semiconductor device; and
wherein the number of the first vias in the first type of vias is n1, wherein the number of the second vias in the second type of vias is n2, and wherein (n1−n2)≤5.

9. The semiconductor device according to claim 1, wherein the semiconductor device further comprises a plurality of sources located at a side of the epitaxial structure opposite the substrate, the sources extending along the first direction, and the plurality of the sources being arranged along the second direction;
wherein the plurality of the sources comprise a first source and a second source, and along the second direction, the first source is disposed adjacent to the first gate and the second source is disposed adjacent to the second gate, and the first source is located at a side of the second source near an edge of the semiconductor device;
wherein the semiconductor device further comprises vias penetrating through the substrate and the epitaxial structure, the vias comprising a first type of vias and a second type of vias, and along a thickness direction of the semiconductor device, the first source is overlapped with the first type of vias, and the second source is overlapped with the second type of vias; and
wherein, along the first direction, a center of the first type of vias is located at a side, which is near to a center of the semiconductor device, of a center of the second type of vias.

10. The semiconductor device according to claim 1, wherein, along the second direction, there is a gate spacing between two of the gates that are adjacent to each other;
wherein a plurality of the gate spacings comprise a first gate spacing along a side of the second direction near an edge of the semiconductor device and a second gate spacing located at a side of the first gate spacing opposite the edge of the semiconductor device; and
wherein, along the second direction, the first gate spacing is less than the second gate spacing.

11. The semiconductor device according to claim 10, wherein the second gate spacing is located at a side of any other gate spacing near a center of the semiconductor device; and
wherein the gate spacing gradually increases along a side of the first gate spacing pointing to the second gate spacing.

12. A method of manufacturing a semiconductor device, for manufacturing the semiconductor device according to claim 1, wherein the method of manufacturing comprising:
providing a substrate;
fabricating an epitaxial structure at a side of the substrate; and
fabricating a plurality of gates at a side of the epitaxial structure opposite the substrate, the gates extending along a first direction, and the plurality of the gates being arranged along a second direction, wherein the first direction and the second direction intersect with each other and are each parallel to a plane where the substrate is located, wherein the plurality of the gates comprise a first gate and a second gate, and along the second direction, the first gate is located at a side of the second gate near an edge of the semiconductor device, wherein the highest temperature of the first gate is T1, wherein the highest temperature of the second gate is T2, and wherein (T2−T1)/T1≤20%.
